(19) United States
(12) Patent Application Publication
(10) Pub. No.: US 2018/0259687 A1
(43) Pub. Date: Sep. 13, 2018

(54) FLEXIBLE BRAGG REFLECTOR

(71) Applicant: SABIC Global Technologies B.V., Bergen op Zoom (NL)

(72) Inventors: Sang Hoon KIM, Seoul (KR); Sung Min CHO, Gyeonggi-do (KR)

(21) Appl. No.: 15/759,853

(22) PCT Filed: Sep. 15, 2016
(86) PCT No.: PCT/IB2016/055511

§ 371 Date: Mar. 14, 2018

Related U.S. Application Data
(60) Provisional application No. 62/220,615, filed on Sep. 18, 2015.

(51) Int. Cl. G02B 5/08; H01L 33/10

(52) U.S. Cl. CPC G02B 5/0841; G02B 1/00; H01L 33/10

(57) ABSTRACT

A flexible Bragg reflector includes a substrate and at least one dyad layer located on the substrate. The at least one dyad layer includes a layer of polymeric material and a layer of inorganic material. The layer of polymeric material has a low refractive index, the layer of inorganic material has a higher refractive index than that of the layer of polymeric material, and the substrate and the at least one dyad layer are flexible. Methods for making a flexible Bragg reflector are also described.

### RELATED APPLICATION

The present application claims priority to and the benefit of U.S. provisional application No. 62/220,615, titled “Flexible Bragg Reflector,” and filed Sep. 18, 2015, the entirety of which is incorporated herein by reference for any and all purposes.

### FIELD OF DISCLOSURE

The present disclosure relates to an optical reflector, and more particularly to an optical reflector including a flexible Bragg reflector.

### BACKGROUND OF THE DISCLOSURE

A distributed Bragg reflector (DBR), also referred to as a Bragg reflector, is a mirror structure that includes an alternating sequence of layers of two different optical materials. One such design is a quarter-wave mirror, in which each optical layer thickness corresponds to one quarter of the wavelength for which the mirror is designed. DBRs are used as spectrally selective mirrors in various applications such as power lasers/optical guiding, precise micromachining and gas/liquid sensing, aberration-free optical imaging, epidermal sensing, chip-to-chip interconnects and broadband photonic tuning, photovoltaics, light emitting diodes (LEDs) and organic light emitting diodes (OLEDs). Conventionally, fabrication of DBRs often entails stacking varying inorganic dielectric thin films, such as TiO₂/SiO₂ and Al₂O₃/HfO₂ bilayers, on plastic substrates. The use of DBRs having these inorganic bilayers is advantageous because they can provide wide bandwidth and high reflectivity with only a few pairs of bilayers, but they are rigid, limiting the range of applications in which they can be used. DBRs have also been made from organic materials, but they have poor water vapor transmission rate (WVTR) properties.

These and other shortcomings of the prior art are addressed by the present disclosure.

### BRIEF DESCRIPTION OF THE FIGURES

The summary, as well as the following detailed description, is further understood when read in conjunction with the appended drawings. For the purpose of illustrating the invention, there are shown in the drawings exemplary aspects of the invention; however, the invention is not limited to the specific methods, compositions, and devices disclosed. In addition, the drawings are not necessarily drawn to scale. In the drawings:

FIG. 1 is a schematic of a Bragg reflector according to aspects of the disclosure.

FIG. 2 is a transmittance curve showing the variation of wavelength with varying numbers of dyad layers.

FIGS. 3A and 3B are transmittance curves illustrating the maximum peak shift of an OLED device having varying numbers of dyad layers with the variation of viewing angle.

### SUMMARY

Aspects of the present disclosure relate to a flexible Bragg reflector including a substrate and at least one dyad layer located on the substrate. The at least one dyad layer includes a layer of polymeric material and a layer of inorganic material. The layer of polymeric material has a low refractive index, the layer of inorganic material has a higher refractive index than that of the layer of polymeric material, and the substrate and at the least one dyad layer are flexible.

Other aspects of the present disclosure relate to a methods for making a flexible Bragg reflector that include applying at least one dyad layer to a substrate, the at least one dyad layer including a layer of polymeric material and a layer of inorganic material. The layer of polymeric material has a low refractive index, the layer of inorganic material has a higher refractive index than that of the layer of polymeric material, and the substrate and the at least one dyad layer are flexible.

### DETAILED DESCRIPTION

The present disclosure can be understood more readily by reference to the following detailed description of the disclosure and the Examples included therein. In various aspects, the present disclosure pertains to a flexible Bragg reflector including a substrate and at least one dyad layer located on the substrate. The at least one dyad layer includes a layer of polymeric material and a layer of inorganic material. In certain aspects, the layer of polymeric material has a low refractive index, the layer of inorganic material has a higher refractive index than that of the layer of polymeric material, and the substrate and the at least one dyad layer are flexible.

Before the present compounds, compositions, articles, systems, devices, and/or methods are disclosed and described, it is to be understood that they are not limited to specific synthetic methods unless otherwise specified, or to particular reagents unless otherwise specified, as such can, of course, vary. It is also to be understood that the terminology used herein is for the purpose of describing particular aspects only and is not intended to be limiting.

Various combinations of elements of this disclosure are encompassed by this disclosure, e.g., combinations of elements from dependent claims that depend upon the same independent claim.

Moreover, it is to be understood that unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that an order be inferred, in any respect. This holds for any possible non-express basis for interpretation, including: matters of logic with respect to arrangement of steps or operational flow; plain meaning derived from grammatical organization or punctuation; and the number or type of aspects described in the specification.

All publications mentioned herein are incorporated herein by reference to disclose and describe the methods and/or materials in connection with which the publications are cited.

### Definitions

It is also to be understood that the terminology used herein is for the purpose of describing particular aspects only and is not intended to be limiting. As used in the specification and in the claims, the term “comprising” can include the aspects “consisting of” and “consisting essentially of.” Unless defined otherwise, all technical and scientific terms used herein have the same meaning as commonly understood by one of ordinary skill in the art to which this disclosure belongs. In this specification and in the claims which follow, reference will be made to a number of terms which shall be defined herein.

As used in the specification and the appended claims, the singular forms “a,” “an” and “the” include plural referents unless the context clearly dictates otherwise. Thus, for example, reference to “a dyad layer” includes two or more dyad layers.

As used herein, the term “combination” is inclusive of blends, mixtures, alloys, reaction products, and the like.

Ranges can be expressed herein as from one particular value, and/or to another particular value. When such a range is expressed, another aspect includes from the one particular value and/or to the other particular value. Similarly, when values are expressed as approximations, by use of the antecedent ‘about,’ it will be understood that the particular value forms another aspect. It will be further understood that the endpoints of each of the ranges are significant both in relation to the other endpoint, and independently of the other endpoint. It is also understood that there are a number of values disclosed herein, and that each value is also herein disclosed as “about” that particular value in addition to the value itself. For example, if the value “10” is disclosed, then “about 10” is also disclosed. It is also understood that each unit between two particular units are also disclosed. For example, if 10 and 15 are disclosed, then 11, 12, 13, and 14 are also disclosed.

As used herein, the terms “about” and “at or about” mean that the amount or value in question can be the value designated some other value approximately or about the same. It is generally understood, as used herein, that it is the nominal value indicated ±10% variation unless otherwise indicated or inferred. The term is intended to convey that similar values promote equivalent results or effects recited in the claims. That is, it is understood that amounts, sizes, formulations, parameters, and other quantities and characteristics are not and need not be exact, but can be approximate and/or larger or smaller, as desired, reflecting tolerances, conversion factors, rounding off, measurement error and the like, and other factors known to those of skill in the art. In general, an amount, size, formulation, parameter or other quantity or characteristic is “about” or “approximate” whether or not expressly stated to be such. It is understood that where “about” is used before a quantitative value, the parameter also includes the specific quantitative value itself, unless specifically stated otherwise.

Unless otherwise stated to the contrary herein, all test standards are the most recent standard in effect at the time of filing this application.

Each of the materials disclosed herein are either commercially available and/or the methods for the production thereof are known to those of skill in the art.

It is understood that the compositions disclosed herein have certain functions. Disclosed herein are certain structural requirements for performing the disclosed functions and it is understood that there are a variety of structures that can perform the same function that are related to the disclosed structures, and that these structures will typically achieve the same result.

### Bragg Reflector:

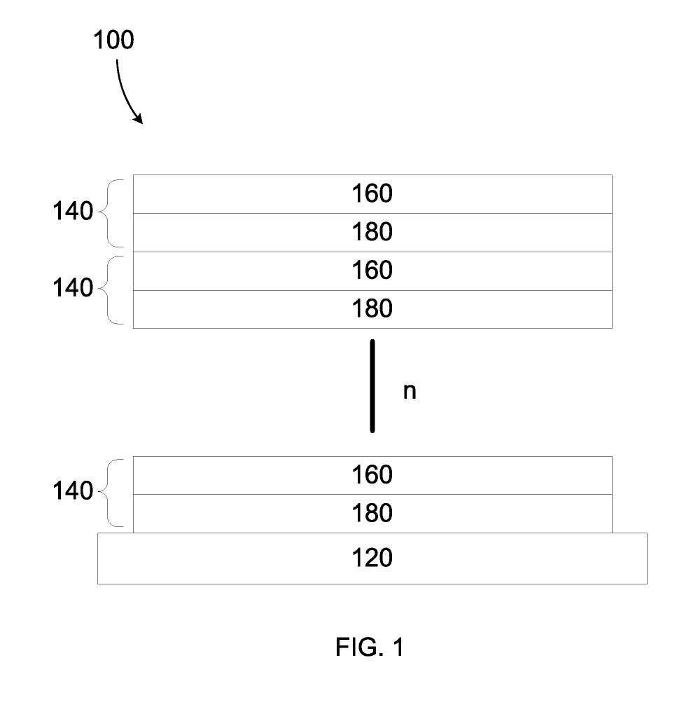

With reference to FIG. 1, aspects of the present disclosure relate to a flexible Bragg reflector 100 including a substrate 120 and at least one dyad layer 140 located on the substrate 120. The at least one dyad layer 140 includes a layer of polymeric material 160 and a layer of inorganic material 180. In certain aspects the layer of polymeric material 160 has a low refractive index, the layer of inorganic material 180 has a higher refractive index than that of the layer of polymeric material, and the substrate 120 and the at least one dyad layer 140 are flexible. The Bragg reflector is suitable for use in various applications, including but not limited to OLED lighting devices and wearable devices such as glasses, clothing, fabrics and watches.

The substrate 120 may be any suitable surface onto which the at least one dyad layer 140 is applied. Suitable substrate materials include, but are not limited to, glass, polymeric (e.g., polyethylene naphthalate (PEN), polycarbonate (PC), polyethylenimine (PEI)), metallic or other materials. In one aspect, the substrate 120 is a flexible substrate 120, such as a flexible polymeric substrate 120. As used herein, “flexible” refers to a material (e.g., substrate, dyad layer, layer of polymeric material or layer of organic material) having a bending radius curvature of about 1 mm to about 100 mm.

In some aspects the substrate 120 (and thus the at least one dyad layer 140 located thereon) is integrated into the system in which the Bragg reflector 100 is incorporated (e.g., an OLED device/assembly, a wearable device, a color tunable device or an optical security system). In other aspects the substrate 120 (and thus the at least one dyad layer 140 located thereon) is separate from the system (e.g., as part of a stand-alone flexible film).

The at least one dyad layer 140 includes a layer of polymeric material 160 and a layer of inorganic material 180.

The layer of polymeric material 160 has a low refractive index. In some aspects the refractive index ranges from about 1.0 to about 1.6. In other aspects the refractive index ranges from about 1.0 to about 1.5. In a particular aspect, the refractive index is about 1.3 to about 1.58.

The layer of polymeric material 160 can have any thickness that provides the desired reflective properties to the Bragg reflector 100. As the thickness of a material varies, refractive index also varies. In some aspects the layer of polymeric material 160 has a thickness of from about 10 nanometers (nm) to about 200 nm, or in some aspects from about 20 nm to about 80 nm.

The polymeric material in the layer of polymeric material 160 can include any polymeric material that provides the desired refractive index. Such materials include, but are certainly not limited to, acrylics, polycarbonates, cellulosics, polyamides, polyurethanes, styrenes, vinyls, and combinations thereof. Further, while the polymeric material is described herein as including a polymeric material, the material could in some aspects be an oligomeric material if it provided the desired refractive index and/or flexibility.

The layer of inorganic material 180 has a higher refractive index than that of the layer of polymeric material 160. In some aspects the refractive index ranges from about 1.5 to about 2.9. In other aspects the refractive index ranges from about 1.5 to about 2.5.

The layer of inorganic material 180 can have any thickness that provides the desired reflective properties to the Bragg reflector. In some aspects the layer of inorganic material 180 has a thickness of from about 10 nm to about 200 nm, or in some aspects from about 20 nm to about 80 nm.

The inorganic material in the layer of inorganic material 180 can include any inorganic material that provides the desired refractive index. Such materials include, but are certainly not limited to, TiO₂, ZnO, ZrO, Al₂O₃, HfO₂, SiOₓ (e.g., SiO, SiO₂, etc.), SiOₓN_{y} (silicon oxynitride), Si₃N₄, MgO and combinations thereof. In some aspects the layer of inorganic material also includes other materials, including but not limited to a polymeric material such as one or more of the polymeric materials described above.

As explained above, the Bragg reflector 100 includes at the least one dyad layer 140 located on the substrate 120. In one aspect, the Bragg reflector 100 includes one dyad layer 140. In other aspects, the Bragg reflector includes 2, 3, 4 or more dyad layers 140, each dyad layer including the layer of polymeric material 160 and the layer of inorganic material 180. In further aspects, the Bragg reflector has “n” dyad layers 140, with n being an integer from 1 to 4.

In certain aspects, both the substrate 120 and the at least one dyad layer 140 (and thus the layer of polymeric material 160 and the layer of inorganic material 180 included therein) of the Bragg reflector 100 are flexible, such that the Bragg reflector 100 is flexible. A flexible Bragg reflector 100 may enhance the suitability of the Bragg reflector for various applications, as discussed below.

In further aspects the Bragg reflector 100 has relatively high water vapor transmission rate (WVTR) properties compared to previous DBRs formed entirely of polymeric/organic materials. A Bragg reflector 100 having a high WVTR will protect the light source (e.g., LED or OLED) from moisture and gases. WVTR is the rate at which water vapor permeates through a film at specified conditions of temperature and relative humidity, and is typically measured in grams per square meter per day (g/m²/day). In certain aspects the Bragg reflector has a WVTR of about 10⁻² to about 10⁻⁶ g/m²/day. In other aspects the Bragg reflector 100 has a WVTR of about 10⁻⁶ g/m²/day. A Bragg reflector 100 having these WVTR properties may enhance the suitability of the Bragg reflector for various applications, as discussed below. WVTR may be determined by any suitable method, including but not limited to a tritium test and a Ca test. Mocon, of Minneapolis, Minn., provides equipment for measuring WVTR of thin films such as those described herein.

The substrate 120 and at the least one dyad layer 140, including the layer of polymeric material 160 and the layer of inorganic material 180 included therein, may be formed according to any suitable method that provides a layer including the desired material and having the desired properties, including but not limited to thickness, refractive index and WVTR. Suitable methods include, but are not limited to, chemical deposition (e.g., plasma enhanced chemical vapor deposition (PECVD) or atomic layer deposition (ALD)), physical deposition (e.g., physical vapor deposition), extrusion, and combinations thereof. In a particular aspect, the layer of polymeric material 160 and the layer of inorganic material 180 are formed by a PECVD method.

The substrate 120 and the at least one dyad layer 140, including the layer of polymeric material 160 and the layer of inorganic material 180 included therein, may adhere to each other during vapor deposition or by other suitable processes.

It should be noted that while FIG. 1 illustrates the Bragg reflector with dyad layers 140 having the layer of inorganic material 180 located between the substrate 120 and the layer of polymeric material 160 such that the layer of inorganic material 180 is proximate the substrate 120, in some aspects the order of the layer of inorganic material 180 and the layer of the polymeric material 160 in one or more of the dyad layers 140 could be reversed such that the layer of polymeric material 160 is located between the layer of inorganic material 180 and the substrate 120 (i.e., the layer of inorganic material 180 faces away from, or is distal, the substrate 120 relative to the layer of polymeric material 160).

### Methods for Making and Using the Bragg Reflector

Aspects of the present disclosure also include methods for making a flexible Bragg reflector 100. The method includes applying at least one dyad layer 140 to a substrate 120, the at least one dyad layer 140 including a layer of polymeric material 160 and a layer of inorganic material 180. The layer of polymeric material 160 has a low refractive index and the layer of inorganic material 180 has a higher refractive index than that of the layer of polymeric material. In one aspect and the substrate 120 and the at least one dyad layer 140 are flexible.

In a certain aspect, the Bragg reflector 100 includes one dyad layer. In other aspects, the Bragg reflector includes a plurality of dyad layers 140, such as from two to four dyad layers 140.

In some aspects, the layer of inorganic material 180 in the at least one dyad layer 140 is proximate the substrate 120 and the layer of polymeric material 160 in the at least one dyad layer 140 is distal the substrate 120. In other aspects, the layer of inorganic material 180 in the at least one dyad layer 140 is distal the substrate 120 and the layer of polymeric material 160 in the at least one dyad layer 140 is proximate the substrate 120.

One or both of the layer of polymeric material 160 and the layer of inorganic material 180 in the at least one dyad layer 140 may be applied by a chemical deposition process such as PECVD or ALD, a physical vapor deposition process, by extrusion or by a combination thereof. In a particular aspect, the layer of polymeric material 160 and the layer of inorganic material 180 in the at least one dyad layer 140 are applied by a PECVD process.

In certain aspects the at least one dyad layer 140 is applied to the substrate by PECVD, with the layer of inorganic material 180 applied to the substrate 120 and the layer of polymeric material 160 applied onto the layer of inorganic material 180 by PECVD processes. Subsequent dyad layers may be applied to the Bragg reflector 100 by PECVD processes. The PECVD process causes each of the layers to adhere to one another. In other aspects, the at least one dyad layer 140 is applied to the substrate by ALD, with the layer of inorganic material 180 applied to the substrate 120 and the layer of polymeric material 160 applied onto the layer of inorganic material 180 by ALD processes. Subsequent dyad layers may be applied to the Bragg reflector 100 by ALD processes. In yet other some combination of deposition processes is used to apply the layers onto one another.

Other aspects, properties and features of the Bragg reflector and its associated components are described above and not duplicated herein.

The Bragg reflector according to aspects described herein may be useful in a wide variety of applications. In some aspects, a Bragg reflector may be incorporated into a wearable device, including but not limited to glasses, an article of clothing, a fabric or a watch. The Bragg reflector, if flexible and having good WVTR properties described herein, is comfortable to wear and suitable for use in such applications, unlike previous DBRs.

In another aspect, the Bragg reflector could be incorporated into a color tunable device. For example, the Bragg reflector could provide color depth and color change as the viewing angle is varied. Such features may be particularly desirable if incorporated into a home appliance as a design or decorative feature.

In a further aspect the Bragg reflector could be incorporated into an optical security system such as a credit card or identity card, which could allow for different colors to be identified as viewing angle is varied. Such features could also be incorporated into a monetary note, which could enhance the counterfeit prevention aspects of the note.

In yet other aspects, the Bragg reflector could be integrated into an OLED lighting device, which could provide the device with an improvement in color rendering index (CRI), provide reliable barrier performance, and add flexibility to the device. Additional aspects in which the Bragg reflector could be used include photonic devices, light recycling displays and sensors.

### Aspects of the Disclosure

In various aspects, the present disclosure pertains to and includes at least the following aspects.

Aspect 1: A flexible Bragg reflector comprising:

a substrate; and

at least one dyad layer located on the substrate, the at least one dyad layer comprising a layer of polymeric material and a layer of inorganic material, wherein the layer of polymeric material has a low refractive index, the layer of inorganic material has a higher refractive index than that of the layer of polymeric material, and the substrate and the at least one dyad layer are flexible.

Aspect 2: The Bragg reflector of Aspect 1, wherein the layer of inorganic material in the at least one dyad layer is proximate the substrate and the layer of polymeric material in the at least one dyad layer is distal the substrate.

Aspect 3: The Bragg reflector of Aspect 1, wherein the layer of inorganic material in the at least one dyad layer is distal the substrate and the layer of polymeric material in the at least one dyad layer is proximate the substrate.

Aspect 4: The Bragg reflector according to any of the previous Aspects, wherein the substrate comprises glass, polymer, metal or a combination thereof.

Aspect 5: The Bragg reflector according to any of the previous Aspects, wherein the Bragg reflector comprises a bending radius curvature of from about 1 mm to about 100 mm.

Aspect 6: The Bragg reflector according to any of the previous Aspects, wherein the layer of polymeric material has a refractive index of from about 1.0 to about 1.6, and the layer of inorganic material has a refractive index of from about 1.5 to about 2.9.

Aspect 7: The Bragg reflector according to any of the previous Aspects, wherein the layer of polymeric material comprises a polymer selected from the group consisting of acrylic, polycarbonate, cellulosic, polyamide, polyurethane, styrene, vinyl, and combinations thereof.

Aspect 8: The Bragg reflector according to any of the previous Aspects, wherein the layer of inorganic material comprises a material selected from the group consisting of TiO₂, ZnO, ZrO, Al₂O₃, HfO₂, SiO, SiO₂, silicon oxynitride, Si₃N₄, MgO and combinations thereof.

Aspect 9: The Bragg reflector according to any of the previous Aspects, wherein the Bragg reflector has a water vapor transmission rate (WVTR) of about 10⁻² to about 10⁻⁶ g/m²/day.

Aspect 10: The Bragg reflector according to any of the previous Aspects, wherein the Bragg reflector comprises from one to four dyad layers.

Aspect 11: A wearable device comprising the flexible Bragg reflector of any of the previous Aspects, the wearable device comprising glasses, an article of clothing, a fabric or a watch.

Aspect 12: A color tunable device, the color tunable device comprising the flexible Bragg reflector of any of Aspects 1 to 10.

Aspect 13: An optical security system, the optical security system comprising the flexible Bragg reflector of any of Aspects 1 to 10.

Aspect 14: The optical security system according to Aspect 13, wherein the optical security system comprises a credit card, identity card, or a monetary note.

Aspect 15: An organic light emitting diode (OLED) assembly, the OLED assembly comprising the flexible Bragg reflector of any of Aspects 1 to 10.

Aspect 16: A method for making a flexible Bragg reflector, the method comprising applying at least one dyad layer to a substrate, the at least one dyad layer comprising a layer of polymeric material and a layer of inorganic material, wherein

the layer of polymeric material has a low refractive index,

the layer of inorganic material has a higher refractive index than that of the layer of polymeric material, and

the substrate and the at least one dyad layer are flexible.

Aspect 17: The method of Aspect 16, wherein the layer of inorganic material in the at least one dyad layer is proximate the substrate and the layer of polymeric material in the at least one dyad layer is distal the substrate.

Aspect 18: The method of Aspect 16, wherein the layer of inorganic material in the at least one dyad layer is distal the substrate and the layer of polymeric material in the at least one dyad layer is proximate the substrate.

Aspect 19: The method of any one of Aspects 16 to 18, wherein one or both of the layer of polymeric material and the layer of inorganic material in the at least one dyad layer are applied to the substrate with a plasma enhanced chemical vapor deposition (PECVD) process or an atomic layer deposition (ALD) process.

Aspect 20: The method of any one of Aspects 16 to 19, wherein the at least one dyad layer comprises from one to four dyad layers.

### EXAMPLES

The following examples are put forth so as to provide those of ordinary skill in the art with a complete disclosure and description of how the compounds, compositions, articles, devices and/or methods claimed herein are made and evaluated, and are intended to be purely exemplary and are not intended to limit the disclosure. Efforts have been made to ensure accuracy with respect to numbers (e.g., amounts, temperature, etc.), but some errors and deviations should be accounted for. Unless indicated otherwise, parts are parts by weight, temperature is in ° C. or is at ambient temperature, and pressure is at or near atmospheric. Unless indicated otherwise, percentages referring to composition are in terms of wt %.

There are numerous variations and combinations of reaction conditions, e.g., component concentrations, desired solvents, solvent mixtures, temperatures, pressures and other reaction ranges and conditions that can be used to optimize the product purity and yield obtained from the described process. Only reasonable and routine experimentation will be required to optimize such process conditions.

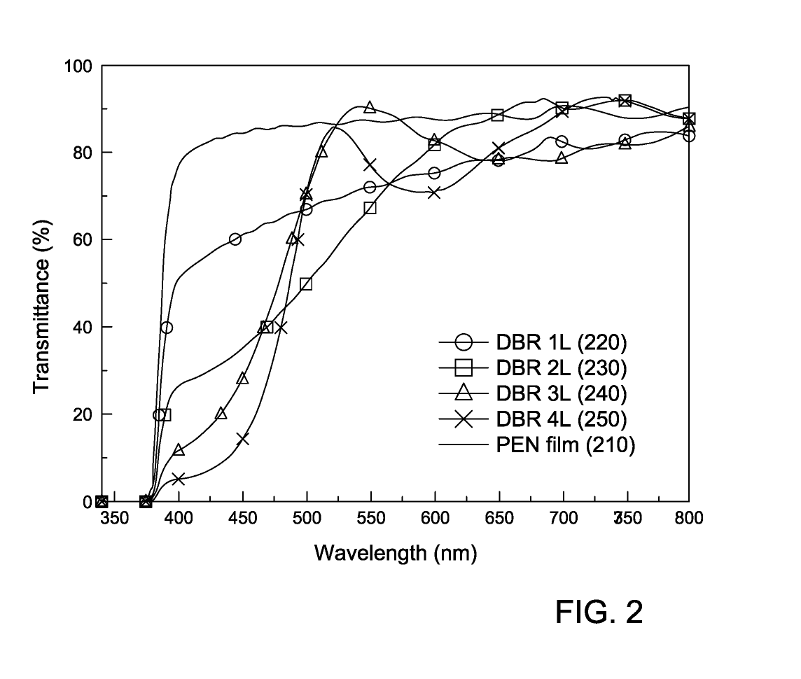

As illustrated in FIG. 2, a transmittance curve showing the variation of wavelength with varying numbers of dyad layers compared to a polyethylene naphthalate (PEN) substrate 210 is provided. Transmittance curves for one dyad layer 220, two dyad layers 230, three dyad layers 240 and four dyad layers 250 are provided. As the number of dyad layers in the Bragg reflector increased, a transmittance cut off below a wavelength of 460 nm was observed, which results in a blue wavelength being reflected by the Bragg reflector, which could be used for applying energy to a color conversion layer such as a phosphor layer in an OLED lighting application. Such a result could contribute to improving the color rendering index value of the OLED.

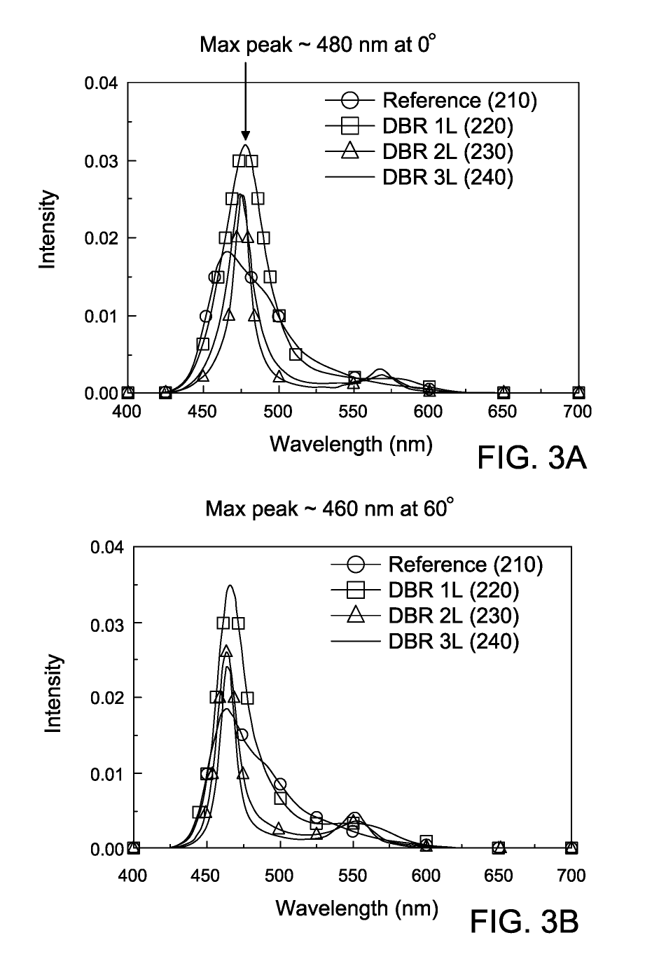

FIGS. 3A and 3B illustrate the maximum peak shift of an OLED device having a varying number of dyad layers (one dyad layer 220, two dyad layers 230, three dyad layers 240 and a reference 210 (a PEN substrate)) with the variation of viewing angle, of from about 480 nm at an angle of 0° to about 460 nm at an angle of 60°. The shift provides for the possibility of using a Bragg reflector according to aspects described herein in a color tunable device. Color depth and change could be provided by varying the viewing angle. Such a feature could also be incorporated into applications such as a home appliance as a design feature to provide color depth and change.

In a further aspect the Bragg reflector could be incorporated into an optical security system such as a credit card or identity card, which could allow for different colors to be identified as viewing angle is varied. Such features could also be incorporated into a monetary note, which could enhance the counterfeit prevention aspects of the note.

It will be apparent to those skilled in the art that various modifications and variations can be made in the present disclosure without departing from the scope or spirit of the disclosure. Other aspects of the disclosure will be apparent to those skilled in the art from consideration of the specification and practice of the disclosure disclosed herein. It is intended that the specification and examples be considered as exemplary only, with a true scope and spirit of the disclosure being indicated by the following claims.

The patentable scope of the disclosure is defined by the claims, and can include other examples that occur to those skilled in the art. Such other examples are intended to be within the scope of the claims if they have structural elements that do not differ from the literal language of the claims, or if they include equivalent structural elements with insubstantial differences from the literal languages of the claims.

1. A flexible Bragg reflector comprising:
a substrate; and
at least one dyad layer located on the substrate, the at least one dyad layer comprising a layer of polymeric material and a layer of inorganic material,
wherein the layer of polymeric material has a low refractive index, the layer of inorganic material has a higher refractive index than that of the layer of polymeric material, and the substrate and the at least one dyad layer are flexible.

2. The Bragg reflector of claim 1, wherein the layer of inorganic material in the at least one dyad layer is proximate the substrate and the layer of polymeric material in the at least one dyad layer is distal the substrate.

3. The Bragg reflector of claim 1, wherein the layer of inorganic material in the at least one dyad layer is distal the substrate and the layer of polymeric material in the at least one dyad layer is proximate the substrate.

4. The Bragg reflector of claim 1, wherein the substrate comprises glass, polymer, metal or a combination thereof.

5. The Bragg reflector of claim 1, wherein the Bragg reflector comprises a bending radius curvature of from about 1 mm to about 100 mm.

6. The Bragg reflector of claim 1, wherein the layer of polymeric material has a refractive index of from about 1.0 to about 1.6, and the layer of inorganic material has a refractive index of from about 1.5 to about 2.9.

7. The Bragg reflector of claim 1, wherein the layer of polymeric material comprises a polymer selected from the group consisting of acrylic, polycarbonate, cellulosic, polyamide, polyurethane, styrene, vinyl, and combinations thereof.

8. The Bragg reflector of claim 1, wherein the layer of inorganic material comprises a material selected from the group consisting of TiO₂, ZnO, ZrO, Al₂O₃, HfO₂, SiO, SiO₂, silicon oxynitride, Si₃N₄, MgO and combinations thereof.

9. The Bragg reflector of claim 1, wherein the Bragg reflector has a water vapor transmission rate (WVTR) of about 10⁻² to about 10⁻⁶ g/m²/day.

10. The Bragg reflector of claim 1, wherein the Bragg reflector comprises from one to four dyad layers.

11. A wearable device comprising the flexible Bragg reflector of claim 1, the wearable device comprising glasses, an article of clothing, a fabric or a watch.

12. A color tunable device, the color tunable device comprising the flexible Bragg reflector of claim 1.

13. An optical security system, the optical security system comprising the flexible Bragg reflector claim 1.

14. The optical security system according to claim 13, wherein the optical security system comprises a credit card, identity card, or a monetary note.

15. An organic light emitting diode (OLED) assembly, the OLED assembly comprising the flexible Bragg reflector of claim 1.

16. A method for making a flexible Bragg reflector, the method comprising applying at least one dyad layer to a substrate, the at least one dyad layer comprising a layer of polymeric material and a layer of inorganic material, wherein
the layer of polymeric material has a low refractive index,
the layer of inorganic material has a higher refractive index than that of the layer of polymeric material, and
the substrate and the at least one dyad layer are flexible.

17. The method of claim 16, wherein the layer of inorganic material in the at least one dyad layer is proximate the substrate and the layer of polymeric material in the at least one dyad layer is distal the substrate.

18. The method of claim 16, wherein the layer of inorganic material in the at least one dyad layer is distal the substrate and the layer of polymeric material in the at least one dyad layer is proximate the substrate.

19. The method of claim 16, wherein one or both of the layer of polymeric material and the layer of inorganic material in the at least one dyad layer are applied to the substrate with a plasma enhanced chemical vapor deposition (PECVD) process or an atomic layer deposition (ALD) process.

20. The method of claim 16, wherein the at least one dyad layer comprises from one to four dyad layers
